(19) United States
(12) Patent Application Publication
(10) Pub. No.: US 2023/0099443 A1
(43) Pub. Date: Mar. 30, 2023

(54) Semiconductor structure and the forming method thereof

(71) Applicant: UNITED MICROELECTRONICS CORP., Hsin-Chu City (TW)

(72) Inventors: Hon-Huei Liu, Kaohsiung City (TW); Shih-Hung Tsai, Tainan City (TW); Chun-Hsien Lin, Tainan City (TW)

(73) Assignee: UNITED MICROELECTRONICS CORP., Hsin-Chu City (TW)

(21) Appl. No.: 17/505,663

(22) Filed: Oct. 20, 2021

(30) Foreign Application Priority Data
Sep. 24, 2021 (CN) 202111119881.5

(51) Int. Cl. H01L 27/11507

(52) U.S. Cl. CPC H01L 27/11507

(57) ABSTRACT

The invention provides a semiconductor structure, which comprises a substrate with at least a first transistor and a second transistor, and a capacitor structure in a dielectric layer above the substrate, wherein the capacitor structure is electrically connected with a gate of the first transistor and a drain of the second transistor.

### BACKGROUND OF THE INVENTION

### 1. Field of the Invention

The present invention relates to the field of semiconductors, in particular to a ferroelectric random access memory (FeRAM) semiconductor structure including two transistors and a capacitor (2T1C) and the forming method thereof.

### 2. Description of the Prior Art

Semiconductor memory devices have been widely used in various electronic devices, such as mobile phones, digital cameras, personal digital assistants, mobile computing devices and other applications.

Transistors and capacitors are common electronic components, and they can be combined with each other to form various circuit patterns. For example, ferroelectric random access memory (FeRAM) is a major memory and an indispensable key component in many electronic products. The FeRAM is composed of a large number of memory cells to form an array area for storing data.

When the above-mentioned electronic components are combined with each other, some errors may occur due to the different environments in which these electronic components are made, which may lead to greater errors when the electronic components are combined into electronic products.

### SUMMARY OF THE INVENTION

The invention provides a semiconductor structure, which comprises a substrate with at least a first transistor and a second transistor on the substrate, and a capacitor structure located in a dielectric layer above the substrate, wherein the capacitor structure is electrically connected with a gate of the first transistor and a drain of the second transistor.

The invention also provides a method for forming a semiconductor structure, which comprises providing a substrate on which at least a first transistor and a second transistor are formed, and forming a capacitor structure in a dielectric layer above the substrate, wherein the capacitor structure is electrically connected with a gate of the first transistor and a drain of the second transistor.

The feature of the present invention is to form a circuit structure of ferroelectric random access memory including two transistors and a capacitor (2T1C). The two transistors are formed in the same layer of the same substrate by the same process, so the two transistors have approximately the same electrical performance, and the quality of the circuit structure can be improved when the circuit structure of the 2T1C ferroelectric random access memory is combined. In addition, a flat conductive layer is additionally formed under the capacitor structure, so that it is less likely to damage the elements below when etching the capacitor structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows the circuit structure of a ferroelectric random access memory composed of two transistors and a capacitor.

FIG. 2 to FIG. 5 are schematic cross-sectional views of a ferroelectric random access memory including two transistors and a capacitor according to an embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

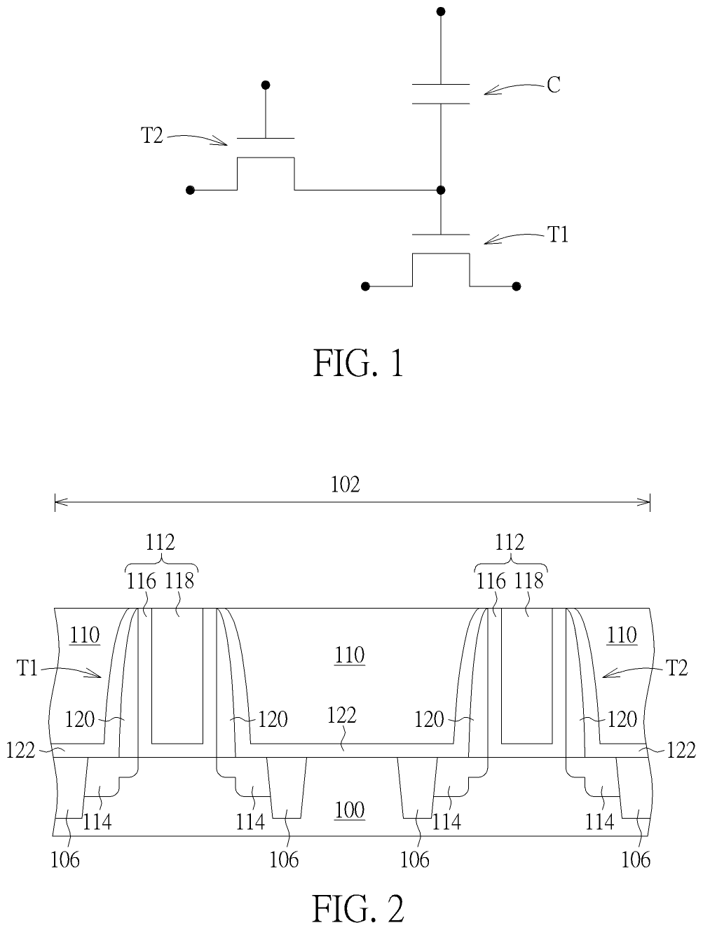

Please refer to FIG. 1 to FIG. 5. FIG. 1 shows a circuit structure diagram of a ferroelectric random access memory composed of two transistors and a capacitor according to the present invention, and FIGS. 2 to 5 show schematic cross-sectional views of a ferroelectric random access memory including two transistors and a capacitor according to an embodiment of the present invention. For convenience of explanation, the drawings of the present invention are only schematic for easier understanding of the present invention, and the detailed scale can be adjusted according to the design requirements. At first, as shown in FIG. 1, a circuit composed of two transistors and a capacitor is provided, which includes a transistor T1, a transistor T2 and a capacitor structure C. The above three components constitute a ferroelectric random access memory (FeRAM) circuit with two transistors and one capacitor (2T1C). In which the capacitor structure C is connected to the gate of the transistor T1 and the drain of the transistor T2 respectively. This kind of circuit has many applications, besides being used as a ferroelectric random access memory unit for storing data, for example, an organic light emitting diode (OLED) can be connected to the drain of the transistor T1, which can be used as a driving circuit for the organic light emitting diode, and the present invention is not limited thereto.

One object of the present invention is to form the above-mentioned 2T1C ferroelectric random access memory circuit. In the conventional technology, transistors formed on different chips or on different layers on the same chip may be bonded or electrically connected with each other by contact structures. However, the applicant found that transistors formed on different chips, or transistors formed on the same chip but located on different layers, will still have differences in actual electrical performance even if they are manufactured by the same process, which is not conducive to the uniformity of transistor specifications, and will also cause errors to the subsequent circuit structure.

To avoid this situation, the present invention is characterized in that two transistors are fabricated on the same layer, and then the two transistors are respectively connected to a capacitor structure to complete a 2T1C ferroelectric random access memory circuit structure. Because the two transistors are formed on the same layer and by the same process, the electrical performance of the two transistors will be close to the same, thus reducing the error of subsequent circuits.

As shown in FIG. 2, a substrate 100 is provided, a semiconductor region 102 is defined on the substrate 100, and a plurality of STI (shallow trench isolation) 106 is then formed on the substrate 100 within the semiconductor region 102. The substrate 100 may be a semiconductor substrate such as silicon substrate, epitaxial silicon substrate, silicon germanium substrate, silicon carbide substrate or silicon-on-insulator (SOI).

A polysilicon gate (not shown) is formed within the semiconductor region 102 as a dummy gate, and after a light doped drain (LDD), a spacer, a source/drain and a dielectric layer are formed, the polysilicon gate is replaced with a metal gate by a gate replacement process and a contact plug process. A bottom ILD (inter layer dielectric) 110 is entirely formed on the substrate 100 by a planarization process such as CMP (chemical mechanical polishing). Up to present step, as shown in FIG. 2, the semiconductor region 102 comprises at least two metal gate structures 112, and a top surface of the metal gate 112 is on the same level as a top surface of the bottom ILD 110.

The metal gate structure 112 at least includes a high-k dielectric layer 116 and at least one metal material layer 118. In which, the high dielectric constant dielectric layer 116 is disposed between the substrate 100 and the metal material layer 118, and can be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrxTi₁-xO₃, PZT) and barium strontium titanate (BaxSr₁—XTiO₃, BST). The metal layer 118 may be adjusted according to the metal gate structure 112 for PMOS or NMOS use, each of them having specific bottom barriers, work function layer, top barriers and main conductive layer.

In addition, on both sides of the metal gate structure 112, a plurality of spacers 120 of single-layer or multi-layer composite structure made of silicon nitride or silicon oxide are formed, and a plurality of doped regions 114 are formed in the substrate 100 on at least one side of the metal gate structure 112. The doped regions 114 include conventional LDD regions (lightly doped drains) and source/drain regions, and the doped regions 114 may additionally include an epitaxial layer, such as silicon germanium epitaxial layer. In addition, a contact etch stop layer (CESL) 122 may be further included between the substrate 100 and the interlayer dielectric layer 110.

Up to the present step, at least two transistors have been formed on the substrate 100, which are respectively defined as transistor T1 and transistor T2, wherein the transistor T1 and transistor T2 are formed by the same process and both are formed in the same layer on the same substrate 100, so the two transistors T1 and T2 should have approximately the same electrical performance. In the conventional technology, if two transistors formed on different layers on the same substrate or two transistors formed on different substrates and bonded to each other are formed under the same process conditions, there will still be a certain difference in the electrical performance of the finally formed transistors due to the influence of the environment. The transistors of the present invention are formed in the same layer on the same substrate and are formed at the same time under the same process conditions, so the influence on environmental changes can be reduced, and the quality of the circuit structure can be further improved.

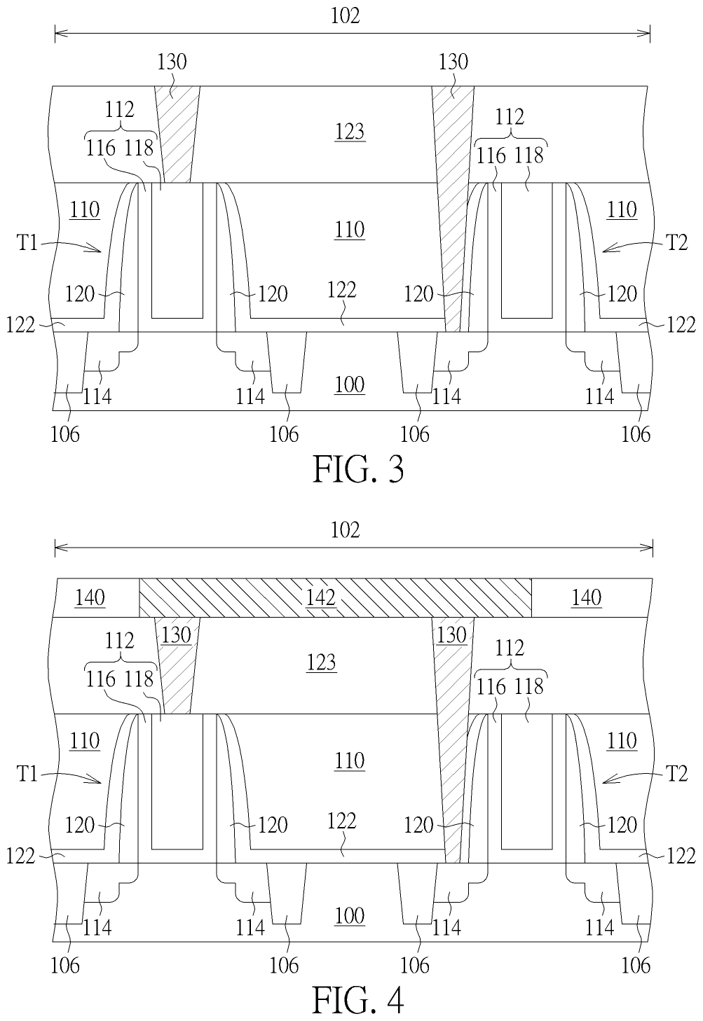

Then, as shown in FIG. 3, another dielectric layer 123 is formed to cover the interlayer dielectric layer 110, and then a plurality of first contacts 130 are formed in the interlayer dielectric layer 110 and/or the dielectric layer 123 in the semiconductor device region 102. The shape of each first contact 130 is not limited, and may include a pole contacts or slot contacts. In this embodiment, the first contact 130 is connected to the gate of the first transistor T1 and the drain of the second transistor T2, respectively, and the two first contact structures 130 will be electrically connected to a capacitor structure in the future to correspond to the circuit structure shown in FIG. 1. The first contact 130 of the present invention can also be formed along with a replacement metal gate (RMG) process, so the first contact 130 can have the same work function metal material and conductive material as the metal gate structure 112, such as aluminum (Al), tungsten (W), copper (Cu), titanium aluminide (TiAl), titanium (Ti), titanium nitride (TiN), tantalum (Ta), tantalum nitride (TaN) or titanium aluminum oxide (TiAlO), etc.

It should be noted that although this preferred embodiment takes a high-k last gate last process as an example, the present invention can also be applied to a high-k first gate last process, a gate first process or a polysilicon gate process, and these processes are well known to those skilled in the art and ordinary people, so they are not added here.

Then, as shown in FIG. 4, a dielectric layer 140 is formed on the dielectric layer 123, and a flat conductive layer 142 is first formed in the dielectric layer 140, wherein the dielectric layer 140 is silicon oxide or silicon nitride, and the material of the flat conductive layer 140 is metal (such as copper in this embodiment), but not limited to this. The dielectric layer 140 is flush with the top surface of the flat conductive layer 142. The flat conductive layer 142 is electrically connected to the first contact 130 and located directly above the first contact 130, and electrically connects the transistor with the capacitor structure to be formed later. In this embodiment, the purpose of forming the flat conductive layer 142 is to define the predetermined formation position of the subsequent capacitor structure, that is, the capacitor structure formed later will be formed on the flat conductive layer 142. In addition, since the dielectric layer 140 has been formed around the flat conductive layer 142, the etching step will stop on the dielectric layer 140 when the capacitor structure is subjected to patterned etching, which is less likely to damage other components below (such as the first contact 130 or the gate structure, etc.).

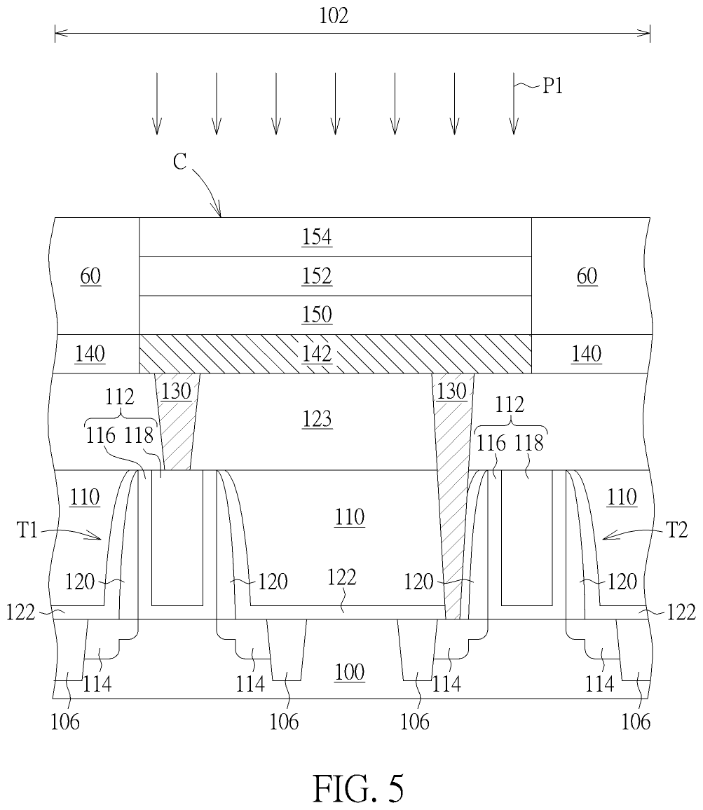

As shown in FIG. 5, after the dielectric layer 140 and the flat conductive layer 142 are completed, a capacitor structure C is formed above the flat conductive layer 142, the capacitor structure C includes a stacked structure of a lower electrode 150, a ferroelectric material layer 152 and an upper electrode 154, and a dielectric layer 160 is included around the capacitor structure C. In this embodiment, the lower electrode 150 and the upper electrode 154 are made of titanium nitride (TiN), the ferroelectric material layer 152 is made of hafnium zirconium oxide (HZO), and the dielectric layer 160 is made of silicon oxide or silicon nitride. The method of forming the capacitor structure C can, for example, first form a lower electrode material layer, a ferroelectric material layer and an upper electrode material layer in sequence, and then perform one or more etching steps to remove the above material layers, and the remaining material layers after etching are respectively the lower electrode 150, the ferroelectric material layer 152 and the upper electrode 154. In addition, in this embodiment, the boundary of the capacitor structure C is flush with the boundary of the flat conductive layer 142, but the present invention is not limited to this. As described above, since the dielectric layer 140 and the flat conductive layer 142 have been formed below, it is less likely to damage other elements in the etching process. After the capacitor structure C is completed, this embodiment performs a rapid heating step (RTP) P1 to make the hafnium zirconium oxide layer more compact. The temperature of RTP step is about 400 degrees Celsius to 450 degrees Celsius, but is not limited to this.

Up to the present step, the capacitor structure C has been electrically connected with the first transistor T1 and the second transistor T2 to form the circuit structure of the ferroelectric random access memory as shown in FIG. 1. Other elements can be formed later, such as contact structures/signal sources which can be connected to the capacitor structure. These steps belong to the conventional technology in the field, and will not be described in detail here.

According to the above description and drawings, the present invention provides a semiconductor structure including a substrate 100 having at least a first transistor T1 and a second transistor T2 thereon, and a capacitor structure C located in a dielectric layer 160 above the substrate, wherein the capacitor structure C is electrically connected to a gate of the first transistor T1 and a drain of the second transistor T2.

In some embodiments of the present invention, the first transistor T1 and the second transistor T2 are located on a same level on the substrate 100.

In some embodiments of the present invention, a flat conductive layer 142 is further included below the capacitor structure C, the material of the flat conductive layer 142 comprises copper and the flat conductive layer 142 directly contacts the capacitor structure C.

In some embodiments of the present invention, at least two contact structures (first contacts) 130 are further included, which are electrically connected to the gate of the first transistor T1, the drain of the second transistor T2 and the flat conductive layer 142.

In some embodiments of the present invention, a width of the flat conductive layer is equal to a width of the capacitor structure C.

In some embodiments of the present invention, the capacitor structure includes an upper electrode 154, a lower electrode 150 and an intermediate ferroelectric material layer.

In some embodiments of the present invention, the ferroelectric material layer 152 comprises hafnium zirconium oxide (HZO).

In addition, the present invention provides a method for forming a semiconductor structure, which includes providing a substrate 100 on which at least a first transistor T1 and a second transistor T2 are formed, and forming a capacitor structure C in a dielectric layer 160 above the substrate 100, the capacitor structure C is electrically connected to a gate of the first transistor T1 and a drain of the second transistor T2.

In addition, the present invention provides a method for forming a semiconductor structure, in which the first transistor T1 and the second transistor T2 are located on a same level on the substrate.

In addition, the present invention provides a method for forming a semiconductor structure, wherein a flat conductive layer 142 is further formed under the capacitor structure C, the material of the flat conductive layer 142 comprises copper, and the flat conductive layer 142 directly contacts the capacitor structure C.

In addition, the present invention provides a method for forming a semiconductor structure, which further comprises forming at least two contact structures 130 electrically connected to the gate of the first transistor T1, the drain of the second transistor T2, and simultaneously electrically connected to the flat conductive layer 142.

The present invention also provides a method for forming a semiconductor structure, wherein a width of the flat conductive layer 142 is equal to a width of the capacitor structure.

In addition, the present invention provides a method for forming a semiconductor structure, wherein the formation steps of the flat conductive layer 142 and the capacitor structure C include forming a flat material layer over the first transistor T1 and the second transistor T2, performing a patterning step on the flat material layer to remove part of the flat material layer, and defining the remaining flat material layer as the flat conductive layer 142, and forming the capacitor structure C on the flat conductive layer.

In addition, the invention provides a method for forming a semiconductor structure, wherein the capacitor structure C comprises an upper electrode 154, a lower electrode 150 and a ferroelectric material layer 152 disposed between the lower electrode 150 and the upper electrode 154.

In addition, the present invention provides a method for forming a semiconductor structure, wherein the ferroelectric material layer 152 is made of hafnium zirconium oxide (HZO).

In addition, the present invention provides a method for forming a semiconductor structure, wherein after the capacitor structure C is formed, it further comprises a rapid heating step P1 for the capacitor structure C.

In addition, the present invention provides a method for forming a semiconductor structure, wherein the temperature of the rapid heating step P1 is between 400 degrees Celsius and 450 degrees Celsius.

The feature of the present invention is to form a circuit structure of ferroelectric random access memory including two transistors and a capacitor (2T1C). The two transistors are formed in the same layer of the same substrate by the same process, so the two transistors have approximately the same electrical performance, and the quality of the circuit structure can be improved when the circuit structure of the 2T1C ferroelectric random access memory is combined. In addition, a flat conductive layer is additionally formed under the capacitor structure, so that it is less likely to damage the elements below when etching the capacitor structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate having at least a first transistor and a second transistor thereon; and
a capacitor structure located in a dielectric layer above the substrate, wherein the capacitor structure is electrically connected to a gate of the first transistor and a drain of the second transistor.

2. The semiconductor structure according to claim 1, wherein the first transistor and the second transistor are located on a same level on the substrate.

3. The semiconductor structure according to claim 1, wherein a flat conductive layer is further included below the capacitor structure, wherein the material of the flat conductive layer comprises copper, and the flat conductive layer directly contacts the capacitor structure.

4. The semiconductor structure according to claim 3, further comprising at least two contact structures electrically connected to the gate of the first transistor, the drain of the second transistor, and simultaneously electrically connected to the flat conductive layer.

5. The semiconductor structure according to claim 3, wherein a width of the flat conductive layer is equal to a width of the capacitor structure.

6. The semiconductor structure according to claim 1, wherein the capacitor structure comprises an upper electrode, a lower electrode and a ferroelectric material layer.

7. The semiconductor structure according to claim 6, wherein the ferroelectric material layer comprises hafnium zirconium oxide (HZO).

8. A method for forming a semiconductor structure, comprising:
providing a substrate;
forming at least a first transistor and a second transistor on the substrate; and
forming a capacitor structure in a dielectric layer above the substrate, wherein the capacitor structure is electrically connected to a gate of the first transistor and a drain of the second transistor.

9. The method according to claim 8, wherein the first transistor and the second transistor are located on a same level on the substrate.

10. The method according to claim 8, wherein a flat conductive layer is further formed under the capacitor structure, wherein the material of the flat conductive layer comprises copper, and the flat conductive layer directly contacts the capacitor structure.

11. The method according to claim 10, further comprising forming at least two contact structures electrically connected to the gate of the first transistor, the drain of the second transistor, and simultaneously electrically connected to the flat conductive layer.

12. The method according to claim 10, wherein a width of the flat conductive layer is equal to a width of the capacitor structure.

13. The method according to claim 10, wherein the step of forming the flat conductive layer and the capacitor structure Comprises:
forming a flat material layer on the first transistor and the second transistor;
performing a patterning step on the flat material layer to remove part of the flat material layer, and defining the remaining flat material layer as the flat conductive layer; and
forming the capacitor structure on the flat conductive layer.

14. The method according to claim 8, wherein the capacitor structure comprises an upper electrode, a lower electrode and a ferroelectric material layer.

15. The method according to claim 14, wherein the ferroelectric material layer comprises hafnium zirconium oxide (HZO).

16. The method according to claim 8, further comprising performing a rapid heating step to the capacitor structure after the capacitor structure is formed.

17. The method according to claim 16, wherein the temperature of the rapid heating step is between 400 degrees Celsius and 450 degrees Celsius.
